(19) United States
(12) Patent Application Publication
(10) Pub. No.: US 2019/0329467 A1
(43) Pub. Date: Oct. 31, 2019

(54) METHOD FOR PRODUCING AN EMC SHIELDING HOUSING, AND EMC SHIELDING HOUSING

(71) Applicant: DIEHL AKO STIFTUNG & CO. KG, Wangen (DE)

(72) Inventor: CHRISTOPH HEINLE, WEITNAU (DE)

(21) Appl. No.: 16/508,750

(22) Filed: Jul. 11, 2019

Related U.S. Application Data
(63) Continuation of application No. PCT/EP2017/000060, filed on Jan. 19, 2017.

(51) Int. Cl. B29C 45/14; B29C 45/00; H05K 9/00

(52) U.S. Cl. CPC B29C 45/14639; B29C 45/14819; H05K 9/0047; H05K 9/009; B29C 45/0013

(57) ABSTRACT

In a method for producing an EMC shielding housing, an EMC active fabric in the form of a prepreg is placed in a molding tool, and is overmolded with at least one plastic component in order to form a plastic molded part or an encapsulation compound integrated into the molded part.

### CROSS-REFERENCE TO RELATED APPLICATION

This is a continuation application, under 35 U.S.C. § 120, of copending international application No. PCT/EP2017/000060, filed Jan. 19, 2017, which designated the United States; the prior application is herewith incorporated by reference in their entirety.

### BACKGROUND OF THE INVENTION

### Field of the Invention

The present invention relates to a method for producing an EMC shielding housing and to a corresponding EMC shielding housing.

EMC shielding housings are used in order to ensure electromagnetic compatibility (EMC) of electronic devices, i.e. to reduce the electromagnetic emission of electronic devices and to protect electronic devices against incoming electromagnetic radiation. The electronic devices which require such EMC shielding include, for example, electric motors, drive elements, control devices, etc. for example in electronic household devices.

It is known to achieve electromagnetic shielding with a metal housing. Particularly for reasons of weight and cost, however, plastic housings are often preferred. In order to produce an EMC active plastic housing, it is for example known to provide the plastic housing with an EMC active coating (metal vapor deposition, conductive coating material, etc.) or to use electrically conductive plastics for the housing.

### SUMMARY OF THE INVENTION

The object of the invention is to provide a further possibility for the production of EMC shielding housings made of plastic.

This object is achieved by the teaching of the independent claims. The dependent claims relate to particularly advantageous configurations and refinements of the invention.

The method according to the invention for producing an EMC shielding housing contains the steps of placing an EMC active fabric in a molding tool and overmolding the EMC active fabric is overmolded with at least one plastic component in the molding tool.

With this method, a plastic housing which has EMC shielding properties can be produced in a straightforward way. Because of the integration of the EMC active fabric during the molding process, no additional method steps are required in order to subsequently provide a plastic housing with EMC shielding properties. Additionally, the use of an EMC active fabric does not restrict the possibilities of shaping the shielding housing.

The shielding housing may in this case be a housing which fully or partially encloses one or more electronic components. The housing may be closed or have one or more of housing openings. Depending on the application, the shielding housing may have various other special properties, for example thermal conductivity, at least partial transparency, and the like.

The molding tool in this context is in principle any desired molding tool which is suitable for an injection molding method. The molding tool may in particular contain one or more cavities, contain one or more injection nozzles, be provided with one or more movable parts, and the like.

The at least one plastic component is in principle any desired plastic material which is suitable for processing in an injection molding method.

The EMC active fabric is in principle any desired fabric which can shield electromagnetic radiation. The shielding effect may, in particular, be achieved by the material properties and the configuration of the fabric. The fabric may preferably be formed from metal, plastic and/or textile fibers. The term “fabric” is in this context intended to include in principle all types of woven, warp-knitted, weft-knitted fabrics, braided and nonwoven fabrics. Fabrics are easy to process and shape. The porosity of the fabric allows easy penetration by the plastic material and therefore good integration.

The term “overmolding” is in this context intended to include full overmolding and at least partial overmolding (for example back-molding) of the fabric.

In one advantageous configuration of the invention, the EMC shielding housing contains a plastic molded part. The EMC active fabric is then preferably overmolded with at least one plastic component in order to form this molded part.

In another advantageous configuration of the invention, the EMC shielding housing contains a plastic molded part and an encapsulation compound integrated into the molded part in order to encapsulate electronics. The EMC active fabric is then preferably overmolded with at least one plastic component in order to form the molded part and/or at least one plastic component in order to form the encapsulation compound.

In one advantageous configuration of the invention the EMC active fabric is placed in the form of a prepreg in the molding tool. A prepreg is an elastic fabric part which is impregnated with a liquid plastic material, so that it can be brought into shape and then stabilized by curing of the plastic material (preferably by means of temperature and/or pressure). The plastic material is preferably a thermoset.

In one advantageous configuration of the invention, the at least one plastic component comprises a thermoplastic for the overmolding of the EMC active fabric. This embodiment variant is advantageous particularly when using a prepreg, since the plastic material in the prepreg is exposed to sufficient temperature and pressure through the thermoplastic so that it can be cured. A subsequent separate curing step can thus be obviated.

The plastic molded part of the EMC shielding housing may optionally be formed from one plastic component or from a plurality of plastic components. In the case of a plurality of plastic components, these may consist of the same plastic material or of different plastic materials.

The EMC shielding housing contains a plastic molded part and an EMC active fabric integrated into the plastic molded part.

With this EMC shielding housing, the same advantages can be achieved as with the production method described above. In relation to the advantages, term explanations and advantageous configurations, reference is made to the comments above.

In one advantageous configuration of the invention, the EMC active fabric is overmolded with at least one plastic component of the plastic molded part.

In another advantageous configuration of the invention, an encapsulation compound for encapsulating electronics is integrated into the plastic molded part. In this case, the EMC active fabric may be overmolded with at least one further plastic component of the encapsulation compound.

Although the invention is illustrated and described herein as embodied in a method for producing an EMC shielding housing, and an EMC shielding housing, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, sectional view of an EMC shielding housing according to one exemplary embodiment of the present invention;

FIG. 2 is a sectional view to explain a production method of the EMC shielding housing according to a first embodiment variant of the invention; and

FIG. 3 is a sectional view to explain the production method of the EMC shielding housing according to a second embodiment variant of the invention.

### DETAILED DESCRIPTION OF THE INVENTION

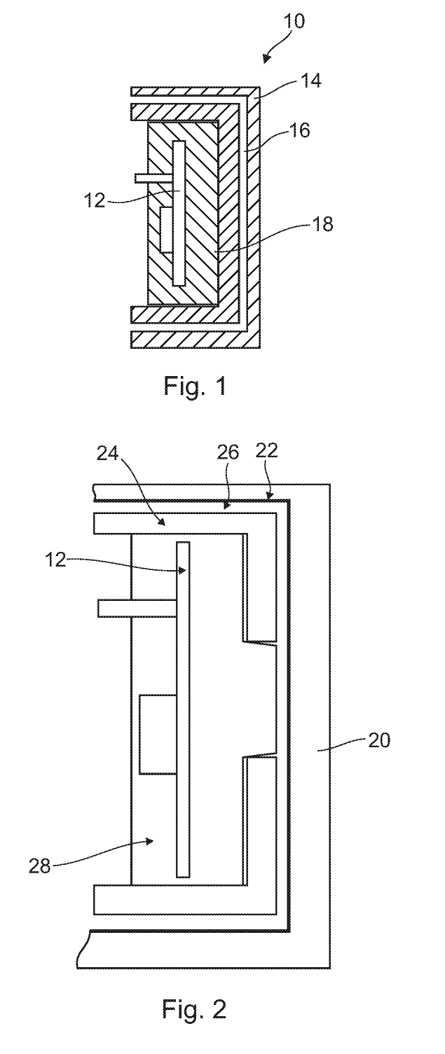

Referring now to the figures of the drawings in detail and first, particularly to FIG. 1 thereof, there is shown a basic structure of an EMC shielding housing 10 according to one exemplary embodiment of invention.

The EMC shielding housing 10 is used for EMC active shielding of electronics 12, which are enclosed at least partially by the EMC shielding housing 10. The electronics 12 include, for example, a circuit board with electronic components of an electronic device, for example of an electric motor, drive element, control device, etc. The electronics 12 with the EMC shielding housing may, for example, be used in electronic household devices such as washing machines, hotplates, cookers, microwave ovens, dishwashers and the like.

The EMC shielding housing 10 contains a plastic molded part 14 made of one or more plastic components, which has been molded by an injection molding method. An EMC active fabric 16 is integrated in the plastic molded part 14. The integration is carried out, for example, by at least partial overmolding of the fabric 16 with at least one plastic component of the plastic molded part, as described below.

The electronics 12 may furthermore be encapsulated in an encapsulation compound 18. The encapsulation compound 18 is preferably molded from a plastic component and is preferably thermally conductive. Besides thermal dissipation and mechanical support of the electronics 12, the encapsulation compound 18 may also be used for electrical insulation of the electronics 12. The electronics 12 with the encapsulation compound 18 may optionally be integrated with the plastic molded part 14, for example by a common injection molding process, or may be inserted as a separate unit into the plastic molded part 14.

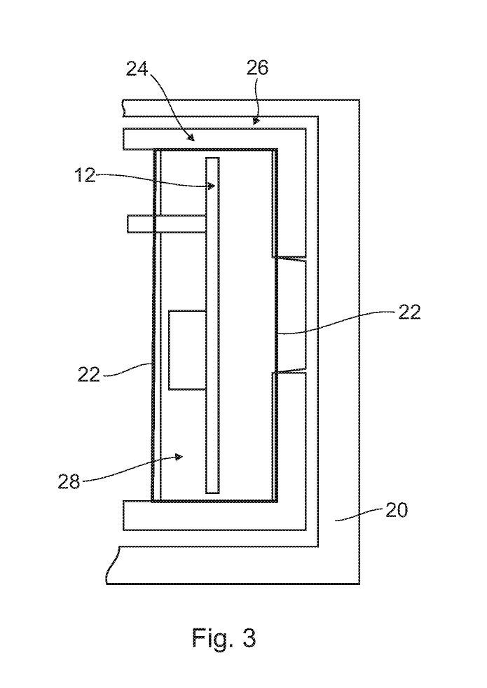

Two variants of a production method for such an EMC shielding housing will be explained in more detail below with the aid of FIGS. 2 and 3. The EMC shielding effect is in this case integrated by composite injection molding, or inline in the injection molding process, into the plastic molded part 14 of the EMC shielding housing 10.

In the embodiment variant of FIG. 2, the integration of the electronics 12 into the EMC shielding housing 10 is carried out in a single manufacturing step with a plurality of injection molding processes carried out sequentially or in parallel in a molding tool 20.

First, the electronics 12 are placed in the molding tool 20. A plastic component 28 is then injected in order to form the encapsulation compound 18. The EMC active fabric 16 in the form of a prepreg 22, i.e. a fabric (for example made of metal, plastic and/or textile fibers) impregnated with a plastic material (for example a thermoset) is then placed in the molding tool.

A first plastic component 24 for forming the plastic molded part 14 is then first injected next to the plastic component 28 for the encapsulation compound 18. The first plastic component 24 preferably consists of a thermally conductive plastic material. The plastic components 24 and 28 in this case fuse together in their transition region.

The prepreg 22 of the EMC active fabric 16 is subsequently back-molded with a second plastic component 26 for the plastic molded part 14. That is to say, the second plastic component 26 is injected between the first plastic component 24 for the molded part 14 and the prepreg 22, and in this case also penetrates through the prepreg 22. The plastic components 24 and 26 in this case fuse together. The second plastic component 26 preferably is formed of an elastomer, by the temperature effect and pressure effect of which during curing of the molded part 14 the plastic material in the prepreg 22 is also cured, and a subsequent curing process can be obviated.

In this embodiment variant, the EMC active fabric 16 is located finally in the outer region of the plastic molded part 14 of the EMC shielding housing 10.

In the embodiment variant of FIG. 3, the integration of the electronics 12 into the EMC shielding housing 10 is likewise carried out in a single manufacturing step with a plurality of injection molding processes carried out sequentially or in parallel in a molding tool 20.

First, the electronics 12 and the EMC active fabric 16 in the form of a prepreg 22, i.e. a fabric impregnated with a plastic material, are placed in the molding tool 20. In this case, the prepreg 22 encloses the electronics 12 at a particular distance therefrom. The plastic component 28 for forming the encapsulation compound 18 is then injected. The plastic component 28 is preferably electrically nonconductive, so that the electronics 12 are insulated from the EMC active fabric 16. The plastic component 28 for the encapsulation compound 18 in this case penetrates at least partially through the prepreg 22.

A first plastic component 24 for forming the plastic molded part 14 is then first injected into the molding tool 20 next to the prepreg 22 and the plastic component 28 for the encapsulation compound 18. The plastic component 28 for the encapsulation compound 18 and the first plastic component 24 for the molded part 14 each preferably consist of a thermally conductive plastic material.

A second plastic component 26 for the molded part 14 is subsequently injected next to the first plastic component 24 for the molded part 14. The second plastic component 26 preferably formed of an elastomer, by the temperature effect and pressure effect of which during curing of the molded part 14 the plastic material in the prepreg 22 is also jointly cured, and a subsequent curing process can be obviated.

In this embodiment variant, the EMC active fabric 16 is located finally between the encapsulation compound 18, encapsulating the electronics 12, and the plastic molded part 14 of the EMC shielding housing 10, the encapsulation compound 18 and the molded part 14 being integrated with one another by the injection molding process.

The invention has been explained with the aid of various exemplary embodiments with reference to FIGS. 1 to 3. The person skilled in the art will easily identify various embodiment variants of the invention which fall within the protective scope defined by the appended claims.

Other features which are considered as characteristic for the invention are set forth in the appended claims.

For instance, in the two embodiment variants of FIGS. 2 and 3, the plastic molded part 14 is respectively formed from two plastic components 24, 26. As an alternative, the molded part 14 may also be formed from just one plastic component or from more than two plastic components.

Furthermore, in the two embodiment variants of FIGS. 2 and 3, the second plastic component 26 for the molded part 14 in each case consists of an elastomer, by the temperature effect and pressure effect of which the plastic material in the prepreg 22 is also jointly cured. If other plastic materials are used for the second plastic component 26, the plastic material in the prepreg 22 may possibly need to be cured in a separate curing process.

Furthermore, the EMC shielding housing 10 encloses the electronics 12 only partially in the two embodiment variants of FIGS. 2 and 3. As an alternative, the molded part 14 of the EMC shielding housing 10 may also enclose the electronics 12 fully. Electrical terminals of the electronics are then, for example, passed through the plastic components 24-26 of the EMC shielding housing 10.

The following is a summary list of reference numerals and the corresponding structure used in the above description of the invention:
10 EMC shielding housing
12 electronics
14 plastic molded part
16 EMC active fabric
18 encapsulation compound
20 molding tool
22 prepreg for EMC active fabric
24 first plastic component for molded part
26 second plastic component for molded part
28 plastic component for encapsulation compound

1. A method for producing an electromagnetic compatibility (EMC) shielding housing, which comprises the steps of:
placing an EMC active fabric in a molding tool; and
overmolding the EMC active fabric with at least one plastic component in the molding tool.

2. The method according to claim 1, which further comprises forming the EMC shielding housing with a plastic molded part by overmolding the EMC active fabric with the at least one plastic component to form the molded part.

3. The method according to claim 1, which further comprises forming the EMC shielding housing with a plastic molded part and an encapsulation compound integrated into the molded part to encapsulate electronics by overmolding the EMC active fabric with the at least one plastic component to form the molded part and/or the at least one plastic component to form the encapsulation compound.

4. The method according to claim 1, which further comprises placing the EMC active fabric, in a form of a prepreg, in the molding tool.

5. The method according to claim 1, wherein the at least one plastic component contains a thermoplastic for the overmolding of the EMC active fabric.

6. The method according to claim 2, which further comprises forming the molded part from a plurality of plastic components.

7. An electromagnetic compatibility (EMC) shielding housing, comprising:
a plastic molded part; and
an EMC active fabric integrated into said plastic molded part.

8. The EMC shielding housing according to claim 7, wherein said EMC active fabric is overmolded with at least one plastic component of said plastic molded part.

9. The EMC shielding housing according to claim 7, wherein:
further comprising an encapsulation compound for encapsulating electronics, said encapsulation compound is integrated into said plastic molded part; and
said EMC active fabric is overmolded with at least one further plastic component of said encapsulation compound.
